(19) United States
(12) Patent Application Publication
(10) Pub. No.: US 2008/0129380 A1
(43) Pub. Date: Jun. 5, 2008

(54) Constant Current Darlington Circuits for High Power

(76) Inventor: Ok-Sang Jin, Seoul (KR)

Correspondence Address: DICKSTEIN SHAPIRO LLP, 1825 EYE STREET NW, Washington, DC, 20006-5403, US

(21) Appl. No.: 11/666,005

(22) PCT Filed: Nov. 4, 2005
(86) PCT No.: PCT/KR05/03729

§ 371 Date: Apr. 23, 2007

(30) Foreign Application Priority Data
Nov. 6, 2004 (KR) 10-2004-0090167

(51) Int. Cl. H03F 3/04

(52) U.S. Cl. 330/250

(57) ABSTRACT

Disclosed herein is a high-power constant current Darlington circuit, including an input terminal in which the base terminal (B) (a first terminal) of the constant current Darlington circuit is connected to the base of a transistor (Q1), the emitter of the transistor (Q1) being connected to one end of a resistor (R1) and the base of a transistor (Q2), the other end of the resistor (R1) being connected to an emitter of the transistor (Q3), the collector terminal (C) (a second terminal) of the constant current Darlington circuit connected to the collector of the transistor (Q1) and the collector of the transistor (Q2), the emitter of the transistor (Q2) being connected to one end of a constant voltage source (CV1), the emitter terminal (E) (a third terminal) of the constant current Darlington circuit directly connected to a load (LD1), the other end of the constant voltage source (CV1) being connected to one end of a resistor (R2) and the base of the transistor (Q3), and the terminal (E1) (a fourth terminal) of the constant current Darlington circuit connected to the other end of the resistor (R2) and the collector of the transistor (Q3), thereby minimizing the loss of power of an output terminal, and a semiconductor device into which the construction is integrated.

### TECHNICAL FIELD

The present application claims priority from Korean Pat. Appl. No. 10-2004-0085369.

A constant current Darlington circuit disclosed in Korean Pat. Appl. No. 10-2003-0063551 (entitled “Darlington circuit, push-pull power amplifier, and Integrated circuit device into which they are integrated”) is related to a technology for use in low power amplifiers.

The technology is described as follows.

FIG. 2 illustrates a circuit that has been proposed in Korean Pat. Appl. No. 10-2003-0063551 (entitled “Darlington circuit, push-pull power amplifier, and Integrated circuit device into which they are integrated”), wherein drive current flows into a load LD21 via a transistor Q22 and a constant voltage source CV21 in order to drive the load LD21. In a high-power circuit where the drive current is large, a large amount of power is consumed in the constant voltage source CV21 that is connected in series to the load. Furthermore, the internal resistance of a drive circuit increases due to the constant voltage source CV21 and, therefore, drive power for driving the load is lowered.

Due to these reasons, a constant current Darlington circuit used for high-power circuits is necessary.

That is, the constant current Darlington circuit, which was proposed in Korean Pat. Appl. No. 10-2003-0063551 (entitled “Darlington circuit, push-pull power amplifier, and Integrated circuit device into which they are integrated”), is a technology used for low-power circuits (theorem 1), and a technology that is proposed in the present invention is a technology that can be used for high-power circuits (theorem 2). Although the technical concepts of the theorem 1 and the theorem 2 are the same, it can be seen that the uses and purposes of them are different from each other.

### BACKGROUND ART

The operation of the circuit for driving the load LD21 is described using FIG. 2.

When an input signal of a terminal IN2 increases, current ibe21 increases accordingly and, thereby, current ice21 of the transistor Q21 also increases. Most of the current ice21 passes through the resistor R21, and voltage between both ends of the resistor R21 increases due to current iR21, thereby increasing the voltage of a node A. The current ibe22 of the transistor Q22 increases due to the increase in the voltage of node A, so that collector current ice22 of a transistor Q22 increases, and impedance between the collector and emitter of the transistor Q22 decreases. Since voltage between both ends of a constant voltage source CV21 connected to the emitter of the transistor Q22 is constant, the electrical potential of a node B increases due to the load LD21 and the electrical potential of a node C also increases. Voltage between both ends of the resistor R21 decreases again as the electrical potential of node C increases, so that the current iR21 decreases and the current ice21 also decreases, therefore the current ice21 is restored to its previous state (the constant current operation of the resistor R21). In this case, the current ibe21 also decreases and, therefore, is restored to its previous state. The transistor Q22 performs control such that the current ice21 is kept constant. The increase of the input signal results only in variation in which the voltage of node B increases and voltage between both ends of the load LD21 increases.

In this case, when the amount of current flowing into the load is large, the amount of current flowing into the constant voltage source CV21 is large, so that the amount of power consumed by the constant voltage source CV21 is large. Furthermore, the internal resistance of the constant current Darlington circuit increases due to the internal resistance of the constant voltage source CV21 and, therefore, drive power for driving the load is lowered. Furthermore, the components of the constant voltage source CV21 must be used for a high-power circuit, and, as a result, the size of the high-power circuit and the component cost thereof increase.

### DISCLOSURE OF INVENTION

### Technical Problem

When the circuit of FIG. 2 is used for a high-power circuit, problems occur in that loss of power increases, power for driving a load is low, the size of the circuit is large, and manufacturing cost increases. Accordingly, the present invention aims to overcome these problems by improving a constant current Darlington circuit for high-power.

### Advantageous Effects

1. The loss of power is low.

2. Power for driving a load is high.

3. Manufacturing cost is low.

4. Input impedance is high.

5. The linearity of an amplification characteristic is excellent.

### BRIEF DESCRIPTION OF THE DRAWINGS

FIG. 1 is a diagram illustrating an example of a first embodiment of a high-power constant current Darlington circuit of the present invention;

FIG. 2 is a diagram illustrating an example of a low-power constant power Darlington circuit;

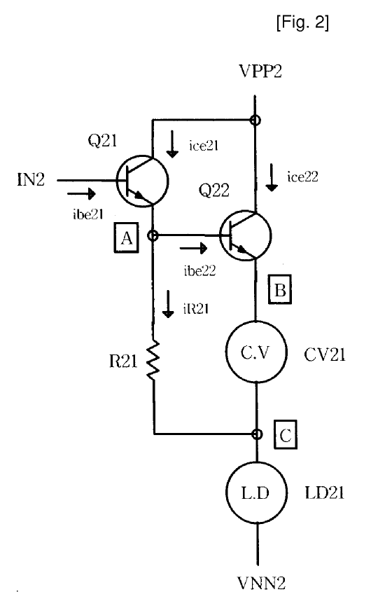

FIG. 3 is a diagram illustrating an example of a buffer power amplifier to which the high-power constant current Darlington circuit of the present invention is applied; and

FIG. 4 is a diagram illustrating an example of a second embodiment of a high-power constant current Darlington circuit of the present invention.

### BEST MODE FOR CARRYING OUT THE INVENTION

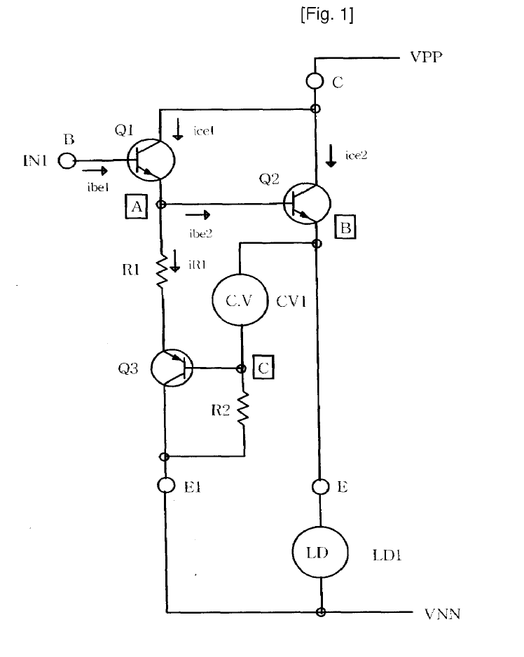

For a first embodiment, FIG. 1 illustrates a high-power constant current Darlington circuit (hereinafter referred to as a “constant current Darlington circuit”).

The construction of FIG. 1 is described below.

The constant current Darlington circuit includes an input terminal in which the base terminal B (a first terminal) of the constant current Darlington circuit is connected to the base of a transistor Q1, the emitter of the transistor Q1 being connected to one end of a resistor R1 and the base of a transistor Q2, the other end of the resistor R1 being connected to an emitter of a transistor Q3, the collector terminal C (a second terminal) of the constant current Darlington circuit connected to the collector of the transistor Q1 and the collector of the transistor Q2, the emitter of the transistor Q2 being connected to one end of a constant voltage source CV1, the emitter terminal E (a third terminal) of the constant current Darlington circuit directly connected to a load LD1, the other end of the constant voltage source CV1 being connected to one end of a resistor R2 and the base of the transistor Q3, and the terminal E1 (a fourth terminal) of the constant current Darlington circuit connected to the other end of the resistor R2 and the collector of the transistor Q3.

### MODE FOR THE INVENTION

In FIG. 1, the constant current Darlington circuit is characterized in that the emitter of the transistor Q2 is directly connected to the load LD1 without intervention of the constant voltage source CV1, and the loss of power is minimized when it is used for a high power circuit. In this case, the resistor R2, connected in series to the constant voltage source CV1, is a resistor for causing bias current to flow into the constant voltage source CV1, and the transistor Q3 plays a role of buffering the voltage of the constant voltage source CV1, and causing current, which flows through the emitter resistor R1 of the transistor Q1, to flow into the terminal E1.

The operation of the constant current Darlington circuit is described using FIG. 1.

When the input signal of a terminal IN1 (terminal B of the constant current Darlington circuit) increases, current ibe1 increases and, thereby, the current ice1 of the transistor Q1 increases. Most of the current ice1 passes through the resistor R1, and voltage between both ends of the resistor R1 increases due to current iR1; therefore, the voltage of node A increases. The current ibe2 of the transistor Q2 increases due to the increase in the voltage of node A, so that collector current ice2 of the transistor Q2 also increases, impedance between the collector and emitter of the transistor Q2 decreases and, therefore, the voltage of node B increases. In this case, increased current ice2 flows into the load LD1 connected to the emitter of the transistor Q2 and, therefore, voltage between both ends of the load LD1 increases. Voltage between both ends of the constant voltage source CV1 connected to the emitter of the transistor Q2 is constant, and voltage of node C, to which the base of the transistor Q3 is connected, increases. The voltage of the emitter of the transistor Q3 increases, so that the voltage between both ends of the resistor R1 connected to the emitter of transistor Q3 decreases again; the current iR1 decreases, and the current ice1 also decreases, therefore, the current ice1 is restored to its previous state (the constant current operation of the transistor R1). In this case, the current ibe1 also decreases and, therefore, is restored to its previous state. The transistor Q2 performs control such that the current ice1 is kept constant. The increase of the input signal results only in variation in which the voltage of node B increases and voltage between both ends of the load LD1 increases. In this case, the current ice2 directly flows into the load LD1, so that, even when a large amount of current flows, the loss of power is low and power for driving the load is high.

The first embodiment is characterized in that the load LD1 is directly connected to the emitter of the transistor Q2, so that current capacity of the constant voltage source CV1 can be low, the size of the circuit can be reduced, and the manufacturing cost of the circuit can be low.

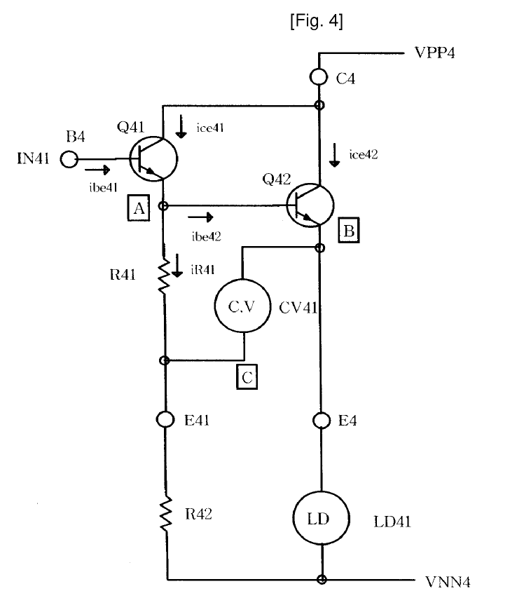

For the second embodiment, the construction of FIG. 4 is described as below.

The constant current Darlington circuit includes an input terminal in which the base terminal B4 (a first terminal) of the constant current Darlington circuit is connected to the base of a transistor Q41, the emitter of the transistor Q41 being connected to one end of a resistor R41 and the base of a transistor Q42, the collector terminal C4 (a second terminal) of the constant current Darlington circuit connected to the collector of the transistor Q41 and the collector of the transistor Q42, the emitter of the transistor Q42 being connected to one end of a constant voltage source CV41, the emitter terminal E4 (a third terminal) of the constant current Darlington circuit directly connected to a load LD41, and the terminal E41 (a fourth terminal) of the constant current Darlington circuit connected to the other end of the constant voltage source CV41, one end of a resistor R41 and one end of an external resistor R42.

In FIG. 4, the constant current Darlington circuit is characterized in that the emitter of the transistor Q42 is directly connected to the load LD41 without intervention of the constant voltage source CV41, and the loss of power is minimized when it is used for a high power circuit. In this case, the resistor R42, connected in series to the constant voltage source CV41, is an external resistor for causing bias current to flow through the constant voltage source CV41 and constant current to flow through the resistor R41.

The operation of the constant current Darlington circuit is described using FIG. 4 below.

When the input signal of a terminal IN41 (terminal B of the constant current Darlington circuit) increases, the current ibe41 increases and, thereby, the current ice41 of the transistor Q41 also increases. Most of the current ice41 passes through the resistor R41, and the voltage between both ends of the resistor R41 increases due to current iR41; therefore, the voltage of node A increases. The current ibe42 of the transistor Q42 increases due to the increase in the voltage of node A, so that collector current ice42 also increases; the impedance between the collector and emitter of the transistor Q42 decreases and, therefore, the voltage of node B increases. In this case, increased current ice42 flows into the load LD1 connected to the emitter of the transistor Q42 and, therefore, voltage between both ends of the load LD41 increases. Since voltage between both ends of the constant voltage source CV41, connected to the emitter of the transistor Q42, is constant, the voltage of node C increases, and the voltage of the other terminal of the resistor R41 increases, so that the voltage between both ends of the resistor R41 decreases again, the current iR41 decreases, and the current ice41 also decreases, therefore the current ice41 is restored to its previous state (constant current operation of the resistor R41). In this case, the current ibe41 also decreases and, therefore, is restored to its previous state. The transistor Q42 performs control such that the current ice41 is kept constant. The increase of the input signal results only in variation in which the voltage of node B increases and the voltage between both ends of the load LD41 increases. In this case, the current ice42 directly flows into the load LD41, so that, even when a large amount of current flows, the loss of power is low and power for driving the load is high.

The second embodiment is characterized in that the load LD41 is directly connected to the emitter of the transistor Q42, so that current capacity of the constant voltage source CV41 can be low, the size of the circuit can be reduced, and the manufacturing cost of the circuit can be low.

The first embodiment of the present invention is appropriate in a case where the amount of the emitter current of the transistor Q1 is large in the high-power circuit of FIG. 1, and the second embodiment of the present invention is appropriate in a case where the amount of the emitter current of the transistor Q41 is small in the high-power circuit of FIG. 4.

The present invention described above is appropriate for use in the output stage device of a power amplifier.

Although, in the present invention, a constant current Darlington circuit formed of NPN transistors is described, the circuit may be formed of PNP transistors.

Although, in FIG. 1, the resistor R2 is exemplified by a fixed resistor, a constant current source may be used instead of the resistor R2.

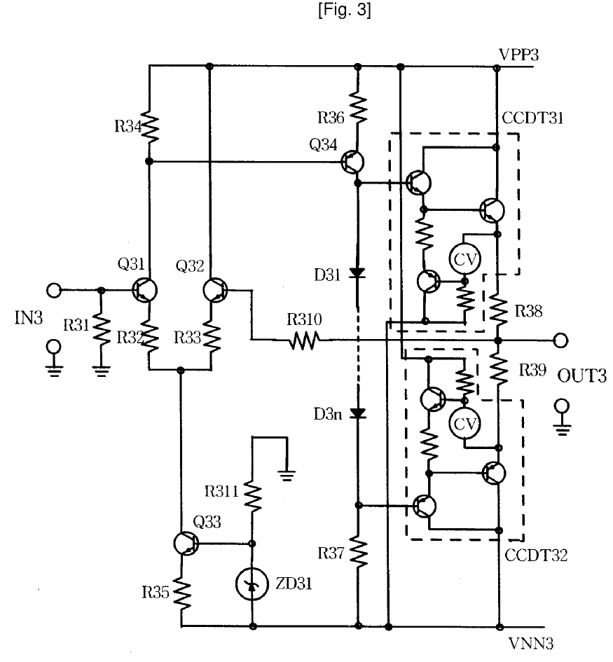

FIG. 3 is an example of a buffer power amplifier to which the high-power constant current Darlington circuit of the present invention is applied. In FIG. 3, reference character CCDT31 indicates a constant current Darlington circuit employing NPN transistors, reference character CCDT32 indicates a constant current Darlington circuit employing PNP transistors.

1. A high-power constant current Darlington circuit, comprising:
an input terminal in which a base terminal (B) (a first terminal) of the constant current Darlington circuit is connected to a base of a transistor (Q1), an emitter of the transistor (Q1) being connected to one end of a resistor (R1) and a base of a transistor (Q2), the other end of the resistor (R1) being connected to an emitter of a transistor (Q3), a collector terminal (C) (a second terminal) of the constant current Darlington circuit connected to a collector of the transistor (Q1) and a collector of the transistor (Q2), an emitter of the transistor (Q2) being connected to one end of a constant voltage source (CV1) and an emitter terminal (E) (a third terminal) of the constant current Darlington circuit, the other end of the constant voltage source (CV1) being connected to one and of a resistor (Ra) and a base of the transistor (Q3), and a terminal (E1) (a fourth terminal) of the constant current Darlington circuit connected to the other end of the resistor (R2) and a collector of the transistor (Q3).

2. A high-power constant current Darlington circuit, comprising:
an input terminal in which a base terminal (B4) (a first terminal) of the constant current Darlington circuit is connected to a base of a transistor (Q41), an emitter of the transistor (Q41) being connected to one end of a resistor (R41) and a base of a transistor (Q42), a collector terminal (C4) (a second terminal) of the constant current Darlington circuit connected to a collector of the transistor (Q41) and a collector of the transistor (Q42), an emitter of the transistor (Q42) being connected to one end of a constant voltage source (CV41) and an emitter terminal (E4) (a third terminal) of the constant current Darlington circuit, and a terminal (E41) (a fourth terminal) of the constant current Darlington circuit connected to the other end of the constant voltage source (CV41), the other end of the resistor (R41) and one end of an external resistor (R42).

3. A semiconductor device into which the construction of claim 1 is integrated.

4. A semiconductor device into which the construction of claim 2 is integrated.

5. A semiconductor device into which the construction of claim 1 is integrated,
wherein a constant current source is used instead of the resistor R2.
